(19) United States
(12) Patent Application Publication
(10) Pub. No.: US 2016/0195578 A1
(43) Pub. Date: Jul. 7, 2016

(54) POWER BANK APPARATUS FOR MEASURING RESISTANCE OF CHARGING LINE

(71) Applicant: Digipower Manufacturing Inc., New Taipei City (TW)

(72) Inventor: Min-Huang Huang, New Taipei City (TW)

(21) Appl. No.: 14/689,048

(22) Filed: Apr. 17, 2015

(30) Foreign Application Priority Data
Jan. 6, 2015 (TW) 104200103

(51) Int. Cl. G01R 27/16; H02J 7/00

(52) U.S. Cl. CPC G01R 27/16; H02J 7/0068; H02J 7/007

(57) ABSTRACT

A power bank apparatus configured to measure resistance of a charging line includes an input port, a first detection circuit, and a processing circuit. Through the charging line, the input port is configured to receive from an external power supply an input power signal as a test signal. The first detection circuit receives the test signal. If the external power supply is in a no-load state, the first detection circuit is configured to detect a voltage of the test signal as a no-load voltage. If the external power supply is in a load state, the first detection circuit is configured to detect the voltage and a current of the test signal as a load voltage and a load current. The processing circuit is coupled to the first detection circuit and receives the no-load voltage, the load voltage, and the load current to calculate the resistance of the charging line.

### CROSS-REFERENCE TO RELATED APPLICATION

This application claims the priority benefit of Taiwan application serial no. 104200103, filed on Jan. 6, 2015. The entirety of the above-mentioned patent application is hereby incorporated by reference herein and made a part of this specification.

### BACKGROUND OF THE INVENTION

1. Field of the Invention

The invention relates to a power supply apparatus; more particularly, the invention relates to a power bank apparatus configured to measure resistance of a charging line (charging cord).

2. Description of Related Art

The rapid development of mobile apparatuses allows normal mobile apparatuses to be equipped with high-resolution screens, to take pictures, to display video clips, to access to a wireless internet connection, and so forth. Said functions of the mobile apparatuses often consume power of batteries in the mobile apparatuses at a fast pace. Accordingly, users of the mobile apparatuses are frequently required to prepare power bank apparatuses for charging the mobile apparatuses and avoiding depletion of power of the batteries.

In most cases, a power bank apparatus is coupled to another power supply (e.g., commercial power) or an electronic apparatus (e.g., a personal computer) through a charging line (or a transmission cable) for power charge. The mobile apparatus is also charged after the mobile apparatus is coupled to the power bank apparatus through the charging line (or the transmission cable). Nevertheless, the charging line (or the transmission cable) has resistance. If a current flowing through the charging line (or the transmission cable) is rather large, an apparent voltage drop is generated across the resistances of the charging line and the connector on the ends of the charging line. Thereby, the voltage output through the charging line may decrease, which poses an impact on the charging action performed on the apparatus (e.g., the power bank apparatus or the mobile apparatus). If the voltage drop resulting from the resistance of the charging line is excessive, the charging action performed on the apparatus may be forced to stop. It can thus be deduced that the resistance of the charging line (or the transmission cable) is a key factor to determine the charging efficiency of the apparatus.

The length of the normal charging lines on the market may be provided to the users, whereas the detailed specifications of the charging lines (e.g., the resistance, the diameter, or the conductive wire material of the charging lines) may not be provided. As such, the users are neither able to learn the impact of the charging line on the charging efficiency of the apparatus nor capable of selecting one of the charging lines with low resistance for enhancing the charging efficiency of the apparatus.

### SUMMARY OF THE INVENTION

The invention is directed to a power bank apparatus configured to measure resistance of a charging line. A user is able to learn an impact of the charging line on a charging efficiency of an apparatus according to the resistance or a diameter of the charging line. The user may also be capable of comparing the resistances or the diameters of plural charging lines and selecting one of the charging lines according to actual design or application requirements.

In an embodiment of the invention, a power bank apparatus configured to measure resistance of a charging line includes at least one input port, at least one first detection circuit, and a processing circuit. The at least one input port is configured to receive from at least one external power supply at least one input power signal as at least one test signal through at least one charging line. The at least one first detection circuit is coupled to the at least one input port to receive the at least one test signal. If the at least one external power supply is in a no-load state, the at least one first detection circuit is configured to detect a voltage of the at least one test signal as at least one no-load voltage. If the at least one external power supply is in a load state, the at least one first detection circuit is configured to detect the voltage and a current of the at least one test signal as at least one load voltage and at least one load current. The processing circuit is coupled to the at least one first detection circuit. The processing circuit receives the at least one no-load voltage, the at least one load voltage, and the at least one load current to calculate the resistance of the at least one charging line.

According to an embodiment of the invention, the power bank apparatus further includes a charge control unit and a battery. The charge control unit is coupled to the at least one input port to receive the at least one test signal. The charge control unit is controlled by the processing circuit, so as to convert the at least one test signal and thereby generate a charge signal. The battery is coupled to the charge control unit and receives the charge signal, so as to be charged.

According to an embodiment of the invention, the battery of the power bank apparatus acts as a load of the at least one external power supply. The processing circuit disables the charge control unit to stop converting the at least one test signal, such that the at least one external power supply is in the no-load state. The processing circuit enables the charge control unit to start converting the at least one test signal, such that the at least one external power supply is in the load state.

According to an embodiment of the invention, the power bank apparatus further includes at least one input/output (I/O) port. The at least one I/O port is coupled to the processing circuit. The processing circuit communicates with at least one external mobile apparatus through the at least one I/O port.

According to an embodiment of the invention, the processing circuit of the power bank apparatus further includes at least one look-up table. The processing circuit receives length information of the at least one charging line from the at least one external mobile apparatus through the at least one I/O port. The processing circuit looks up a diameter of the at least one charging line from the at least one look-up table according to the resistance and the length information of the at least one charging line. The processing circuit outputs the diameter of the at least one charging line to the at least one external mobile apparatus through the at least one I/O port.

According to an embodiment of the invention, the at least one external mobile apparatus includes a mobile application (APP). The length information of the at least one charging line is provided to the processing circuit of the power bank apparatus through the APP. The APP is configured to display the diameter of the at least one charging line.

According to an embodiment of the invention, the at least one look-up table includes a plurality of unit length resistances and a plurality of reference cord diameters. Each of the unit length resistances corresponds to one of the reference cord diameters.

According to an embodiment of the invention, the at least one look-up table corresponds to at least one conductive wire material.

According to an embodiment of the invention, the processing circuit of the power bank apparatus outputs the resistance of the at least one charging line to the at least one external mobile apparatus through the at least one I/O port. The APP of the at least one external mobile apparatus looks up a diameter of the at least one charging line from the at least one look-up table of the APP according to the resistance of the at least one charging line and length information of the at least one charging line, and the APP is configured to display the diameter of the at least one charging line.

According to an embodiment of the invention, the power bank apparatus further includes a discharge control unit. The discharge control unit is coupled between the battery and the at least one I/O port. The discharge control unit is controlled by the processing circuit, so as to convert a voltage of the battery and thereby generate at least one discharge signal. The at least one I/O port receives the at least one discharge signal as at least one output power signal and provides the at least one output power signal to the at least one external mobile apparatus.

In view of the above, the power bank apparatus described herein can serve to measure the resistance of the charging line. Thereby, the user is able to learn the impact of the charging line on the charging efficiency of the apparatus according to the resistance or the diameter of the charging line. The user can also determine whether the charging line is malfunctioned according to the resistance or the diameter of the charging line, whereby the user can then determine whether to replace the charging line or not. The user may also be capable of comparing the resistances or the diameters of plural charging lines and selecting one of the charging lines according to actual design or application requirements.

Several exemplary embodiments accompanied with figures are described in detail below to further describe the invention in details.

### BRIEF DESCRIPTION OF THE DRAWINGS

The accompanying drawings are included to provide a further understanding of the invention, and are incorporated in and constitute a part of this specification. The drawings illustrate exemplary embodiments of the invention and, together with the description, serve to explain the principles of the invention.

FIG. 1 is a schematic block diagram illustrating a power bank apparatus configured to measure resistance of a charging line according to an embodiment of the invention.

FIG. 2 schematically illustrates a method of measuring resistance of a charging line by using the power bank apparatus depicted in FIG. 1.

FIG. 3 schematically illustrates another method of measuring resistance of a charging line by using the power bank apparatus depicted in FIG. 1.

### DETAILED DESCRIPTION OF DISCLOSED EMBODIMENTS

Descriptions of the invention are given with reference to the exemplary embodiments illustrated with accompanied drawings, wherein same or similar parts are denoted with same reference numerals. In addition, whenever possible, identical or similar reference numbers stand for identical or similar elements in the figures and the embodiments.

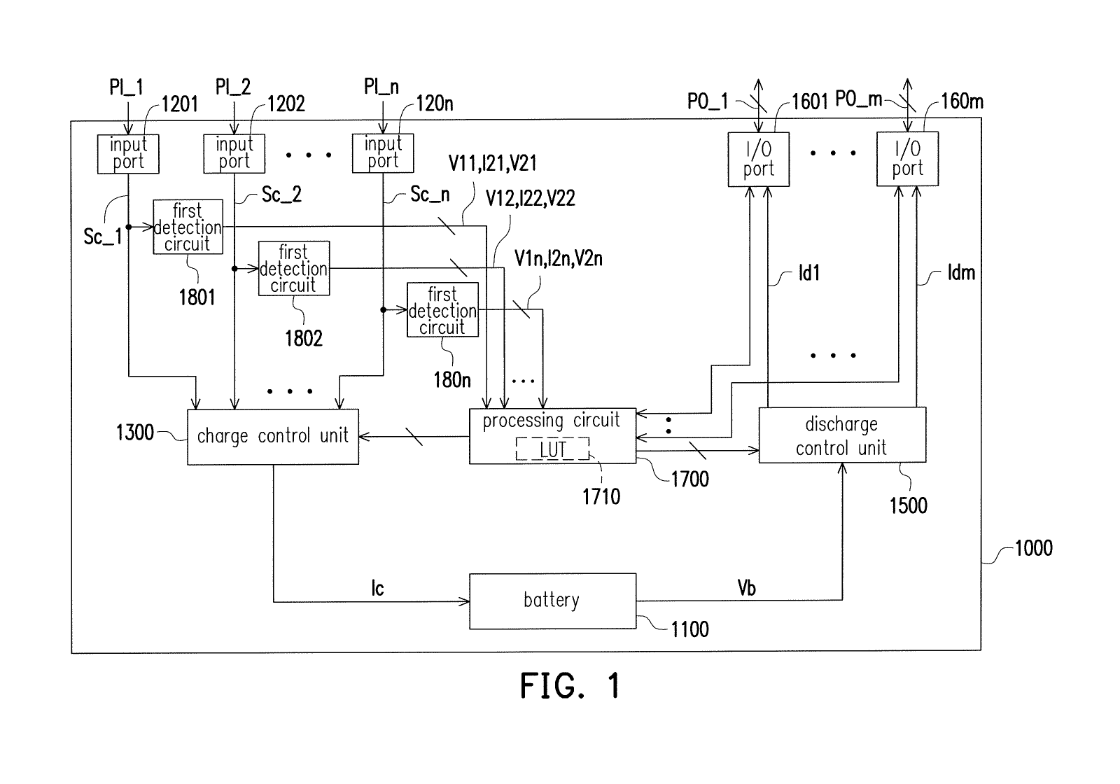

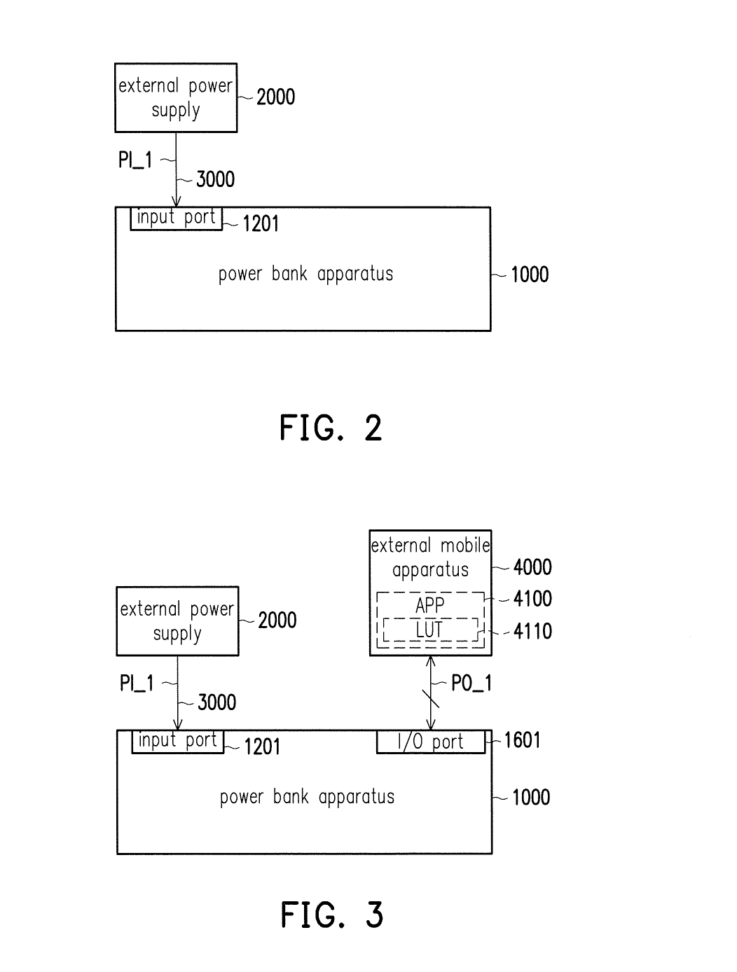

Please refer to FIG. 1 and FIG. 2 together. FIG. 1 is a schematic block diagram illustrating a power bank apparatus 1000 configured to measure resistance of a charging line according to an embodiment of the invention. FIG. 2 schematically illustrates a method of measuring resistance of a charging line 3000 by using the power bank apparatus 1000 depicted in FIG. 1. For illustrative purposes, the power bank apparatus 1000 shown in FIG. 2 includes only one input port 1201. As shown in FIG. 1, the power bank apparatus 1000 may include a battery 1100, at least one input port 1201-120n, a charge control unit 1300, a discharge control unit 1500, at least one input/output (I/O) port 1601-160m, a processing circuit 1700, and at least one first detection circuit 1801-180n.

The at least one input port 1201-120n is configured to receive from at least one external power supply (e.g., an external power supply 2000) at least one input power signal PI_1-PI_n (e.g., the input power signal PI_1) as at least one test signal Sc_1-Sc_n (e.g., the test signal Sc_1) through at least one charging line (e.g., the charging line 3000).

In an embodiment of the invention, the at least one input port 1201-120n may be at least one universal serial bus (USB) input port, and the charging line may be a USB charging line/transmission cable. However, the invention should not be construed as limited to the embodiments set forth herein. In an embodiment of the invention, the at least one input port 1201-120n may be of various types, e.g., micro-USB input ports, mini-USB input ports, etc. The charging line may be any type of USB charging line/transmission cable, e.g., a micro-USB charging line/transmission cable, a mini-USB charging line/transmission cable, etc.

The at least one first detection circuit 1801-180n is coupled to the at least one input port 1201-120n to receive the at least one test signal Sc_1-Sc_n. If the at least one external power supply (e.g., the external power supply 2000) is in a no-load state, the at least one first detection circuit 1801-180n (e.g., the first detection circuit 1801) is configured to detect a voltage of the at least one test signal Sc_1-Sc_n (e.g., the test signal Sc_1) as at least one no-load voltage V11-V1n (e.g., the no-load voltage V11). If the at least one external power supply (e.g., the external power supply 2000) is in a load state, the at least one first detection circuit 1801-180n (e.g., the first detection circuit 1801) is configured to detect the voltage and a current of the at least one test signal Sc_1-Sc_n (e.g., the test signal Sc_1) as at least one load voltage V21-V2n (e.g., the load voltage V21) and at least one load current I21-I2n (e.g., the load current I21).

According to an embodiment of the invention, each first detection circuit (e.g., the first detection circuit 1801) may include one voltage detection circuit (not shown) and one current detection circuit (not shown), which should however not be construed as limitations to the invention. The voltage detection circuit in each first detection circuit (e.g., the first detection circuit 1801) may detect the voltage of the test signal (e.g., the test signal Sc_1) as the no-load voltage (e.g., the no-load voltage V11) or the load voltage (e.g., the load voltage V21). The current detection circuit in each first detection circuit (e.g., the first detection circuit 1801) may detect the current of the test signal (e.g., the test signal Sc_1) as the load current (e.g., the load current I21).

The processing circuit 1700 is coupled to the at least one first detection circuit 1801-180n. The processing circuit 1700 receives the at least one no-load voltage V11-V1n, the at least one load voltage V21-V2n, and the at least one load current I21-I2n to calculate the resistance of the charging line 3000.

The charge control unit 1300 is coupled to the at least one input port 1201-120n to receive the at least one test signal Sc_1-Sc_n. The charge control unit 1300 is controlled by the processing circuit 1700, so as to convert the at least one test signal Sc_1-Sc_n and thereby generate a charge signal Ic. Besides, the charge control unit 1300 is coupled to the battery 1100. The charge control unit 1300 charges the battery 1100 according to the charge signal Ic. According to an embodiment of the invention, the charge control unit 1300 may include a plurality of direct-current (DC) boost circuits (not shown) and a voltage-to-current conversion circuit (not shown). However, the invention should not be construed as limited to the embodiments set forth herein. The DC boost circuits in the charge control unit 1300 can respectively perform a voltage boost on the at least one test signal Sc_1-Sc_n and thereby generate a first boost signal. The voltage-to-current conversion circuit in the charge control unit 1300 can perform a voltage-to-current conversion on the first boost signal, so as to generate the charge signal Ic. The voltage-to-current conversion circuit in the charge control unit 1300 outputs the charge signal Ic to the battery 110, so as to charge the battery 1100.

The battery 1100 may stand for one single battery (or a battery device), a battery set, or a module that includes one or more batteries (or battery devices). Besides, the battery 1100 may be a rechargeable battery, such as a nickel-zinc battery, a nickel-metal hydride (NiMH) battery, a lithium battery, and so on, which should however not be construed as a limitation to the invention.

The discharge control unit 1500 is coupled to the battery 1100. The discharge control unit 1500 is controlled by the processing circuit 1700, so as to convert a voltage Vb of the battery 1100 and thereby generate at least one discharge signal Id1-Idm. According to an embodiment of the invention, the discharge control unit 1500 may include a DC boost circuit (not shown) and a voltage-to-current conversion circuit (not shown). However, the invention should not be construed as limited to the embodiments set forth herein. The DC boost circuit in the discharge control unit 1500 can perform a voltage boost on the voltage Vb of the battery 1100 and thereby generate a second boost signal. The voltage-to-current conversion circuit in the discharge control unit 1500 can perform a voltage-to-current conversion on the second boost signal, so as to generate the at least one discharge signal Id1-Idm.

The at least one I/O port 1601-160m is coupled to the processing circuit 1700 and the discharge control unit 1500. The processing circuit 1700 may communicate with at least one external mobile apparatus through the at least one I/O port 1601-160m. Besides, the at least one I/O port 1601-160m may receive the at least one discharge signal Id1-Idm as at least one output power signal PO_1-PO_m. The at least one I/O port 1601-160m may provide the at least one output power signal PO_1-PO_m to at least one external mobile apparatus, so as to supply power to the at least one external mobile apparatus. According to an embodiment of the invention, the at least one I/O port 1601-160m may be at least one USB port. However, the invention should not be construed as limited to the embodiments set forth herein. According to an embodiment of the invention, the at least one I/O port 1601-160m may be at least one USB port of various types.

In the previous embodiment of the invention, the processing circuit 1700 may be implemented in form of a micro processor, a digital signal processor (DSP), an application specific integrated circuit (ASIC), or a field programmable gate array (FPGA). The charge control unit 1300, the discharge control unit 1500, and the at least one first detection circuit 1801-180n may be implemented in form of ASIC or FPGA. Here, the processing circuit 1700, the charge control unit 1300, the discharge control unit 1500, and the at least one first detection circuit 1801-180n may be formed on one individual circuit chip or may be partly or wholly formed on one integrated circuit chip, which should however not be construed as a limitation to the invention.

The operation of the power bank apparatus 1000 will be elaborated hereinafter. For illustrative purposes, the following power bank apparatus 1000 exemplarily measures resistance of one charging line, for instance. The method of measuring resistances of plural charging lines by the power bank apparatus 1000 can be deduced from the following description.

Please refer to FIG. 1 and FIG. 2 together. As shown in FIG. 2, the external power supply 2000 is coupled to the input port 1201 of the power bank apparatus 1000 through the charging line 3000. Through the charging line 3000, the input port 1201 is configured to receive from the external power supply 2000 the input power signal PI_1 as the test signal Sc_1. Given different load states of the external power supply 2000, the power bank apparatus 1000 is able to detect the voltage and the current of the test signal Sc_1 and obtain the resistance or the diameter of the charging line 3000 according to the detection result. In the present embodiment, the external power supply 2000 may be the commercial power or any electronic apparatus capable of supplying power, the charging line 3000 may be a USB charging line or transmission cable of various types, and the input port 1201 may be compatible with the specifications of the charging line 3000. Note that the invention should not be construed as limited to the embodiments set forth herein.

For instance, in the present embodiment, it is assumed that the external power supply 2000 is able to output the power signal with the voltage at 5 volts and the current in 2 amperes (i.e., the output power is 10 watts). When the power bank apparatus 1000 is not yet charged by the external power supply 2000, no current flows through the charging line 3000, and the external power supply 2000 is thus in a no-load state. Hence, the voltages at both ends of the charging line 3000 are 5 volts. That is, the voltage of the test signal Sc_1 received by the first detection circuit 1801 is substantially equal to the 5-V output voltage of the external power supply 2000. At this time, the first detection circuit 1801 is able to detect the voltage of the test signal Sc_1 as 5 volts, and the detected voltage serves as the no-load voltage V11. That is, the no-load voltage V11 is the output voltage of the external power supply 2000.

On the other hand, if the power bank apparatus 1000 starts to be charged by the external power supply 2000, current flows from the external power supply 2000 to the power bank apparatus 1000 through the charging line 3000, and the external power supply 2000 is thus in a load state. Due to the resistance of the charging line 3000, voltage drop is generated across both ends of the charging line 3000 while the current flows from the external power supply 2000 to the power bank apparatus 1000. Although the external power supply 2000 may output the voltage at 5 volts, the voltage received by the input port 1201 of the power bank apparatus 1000 is less than 5 volts because of the power consumption caused by the resistance of the charging line 3000. That is, the voltage of the test signal Sc_1 received by the first detection circuit 1801 of the power bank apparatus 1000 is less than 5 volts. At this time, the first detection circuit 1801 is able to detect the voltage and the current of the test signal Sc_1, and the detected voltage and the detected current respectively serve as the load voltage V21 and the load current I21.

In the previous embodiment, the load voltage V21 detected by the first detection current 1801 is assumed to be 4.8 volts, and the load current I21 detected by the first detection circuit 1801 is assumed to be 2 amperes. Hence, the voltage difference at two ends of the charging line 3000 is 0.2 volt obtained by subtracting the load voltage V21 from the no-load voltage V11, and the current flowing through the charging line 3000 is 2 amperes (i.e., the load current I21). Thereby, the processing circuit 1700 is able to calculate the resistance of the charging line 3000 as 0.1 ohm according to the no-load voltage V11 (5 volts), the load voltage V21 (4.8 volts), and the load current I21 (2 amperes). Namely, the processing circuit 1700 can obtain the resistance of the charging line 300 through an equation (1). Here, R in the equation (1) stands for the resistance of the charging line 300.

R=(V11−V21)÷I21 (1)

As provided above, the charge control unit 1300 is controlled by the processing circuit 1700, so as to convert the test signal Sc_1 and thereby generate the charge signal Ic, and the battery 1100 may be charged according to the charge signal Ic. Therefore, according to an embodiment of the invention, the battery 1100 may act as the load of the external power supply 2000. However, the invention should not be construed as limited to the embodiments set forth herein.

The processing circuit 1700 may disable the charge control unit 1300 to stop converting the test signal Sc_1 and stop charging the battery 1100. Thereby, the external power supply 2000 is in the no-load state. Namely, since the charge control unit 1300 is disabled, the charging path between the external power supply 2000 and the battery 1100 is turned off. The external power supply 2000 is thus in the no-load state, and no current flows through the charging line 3000 at this time.

By contrast, the processing circuit 1700 may enable the charge control unit 1300 to start converting the test signal Sc_1 and start charging the battery 1100. Thereby, the external power supply 2000 is in the load state. Namely, since the charge control unit 1300 is enabled, a charging path may be constituted by the external power supply 2000, the charging line 3000, the input port 1201, the charge control unit 1300, and the battery 1100. The external power supply 2000 can accordingly charge the battery 1100 and is thus in the load state, and current flows through the charging line 3000 at this time.

According to another embodiment of the invention, an external mobile apparatus may also act as the load of the external power supply 2000. Please refer to FIG. 1 and FIG. 3 together. FIG. 3 schematically illustrates another method of measuring resistance of the charging line 3000 by using the power bank apparatus 1000 depicted in FIG. 1. Different from the measurement method shown in FIG. 2, the measurement method shown in FIG. 3 discloses that an external mobile apparatus 4000 is coupled to the I/O port 1601 and then acts as the load of the external power supply 2000. The discharge control unit 1500 can thus be controlled by the processing circuit 1700, so as to convert a voltage Vb of the battery 1100 and thereby generate at the discharge signal Id1. The I/O port 1601 may receive the discharge signal Id1 as the output power signal PO_1 and provide the output power signal PO_1 to the external mobile apparatus 4000, so as to supply power to the external mobile apparatus 4000. Thereby, even though the battery 1100 is fully charged, the measurement of the resistance of the charging line 3000 by the power bank apparatus 1000 is not terminated. The external mobile apparatus 4000 includes and is not limited to a mobile phone, a tablet PC, a power bank, a handheld game console, and so on. It is also possible for two or more external mobile apparatuses 4000 to act as the load of other external power supplies 2000, and the relevant embodiments can be deduced from the above descriptions and thus will not be elaborated hereinafter.

In the previous embodiment, the processing circuit 1700 can obtain the resistance R of the charging line 3000 through the equation (1) and output the resistance R of the charging line 3000 for the user's reference. However, the resistance R may not be sufficient for normal users. According to an equation of the resistance R (R=ρ×L/A), the resistance R of the charging line 3000 is in proportion to the length L of the charging line 3000 and is in an inverse proportion to the cross-sectional area A of the charging line 3000 (or the square of the diameter of the charging line 3000). Here, ρ stands for resistivity, which is relevant to the conductive wire material of the charging line 3000. The length L of the charging line 3000 is frequently known to the users (i.e., may be provided by manufacturers or measured by the users themselves); hence, in an embodiment of the invention, the user may provide the length L of the charging line 3000, and the processing circuit 1700 may provide the diameter (or the conductive wire material) of the corresponding charging line 3000 for the user's reference according to the length L provided by the user and the calculated resistance R of the charging line 3000. Detailed explanations are given below.

Please refer to FIG. 1 and FIG. 3 together. According to an embodiment of the invention, the processing circuit 1700 may include a look-up table (LUT) 1710. The processing circuit 1700 may receive length information L of the charging line 3000 from the external mobile apparatus 4000 through the I/O port 1601. The processing circuit 1700 looks up the diameter size or the cross-sectional area of the charging line 3000 from the LUT 1710 according to the resistance R and the length information L of the charging line 3000. The diameter size of the charging line 3000 can be represented in American wire gauge (AWG) or in unit of inches or millimeters, and the cross-sectional area may be represented by square millimeters (mm²). However, the invention should not be construed as limited to the embodiment set forth herein. The processing circuit 1700 may output the diameter size of the charging line 3000 to the external mobile apparatus 4000 through the I/O port 1601.

According to the previous embodiment of the invention, the external mobile apparatus 4000 may further include a designated mobile application (APP) 4100. The length information L of the charging line 300 can be provided to the processing circuit 1700 of the power bank apparatus 1000 through the APP 4100. The APP 4100 may further display the diameter size of the charging line 3000. However, the invention should not be construed as limited to the embodiments set forth herein.

According to an embodiment of the invention, the LUT 1710 built in the processing circuit 1700 may be shown by Table 1. As shown by Table 1, the LUT 1710 includes a plurality of unit length resistances Rᵤ and a plurality of reference cord diameters Aᵣ of a copper wire, and each of the unit length resistances Rᵤ corresponds to one of the reference cord diameters Aᵣ. The unit length resistances Rᵤ of the copper wire is in unit of ohm/m, and the reference cord diameter Aᵣ is in unit of AWG; however, the invention should not be construed as limited to the embodiments set forth herein. In the LUT 1710 shown by Table 1, the unit length resistances Rᵤ of the copper wire and the corresponding reference cord diameter Aᵣ can be obtained by performing tests in advance. The LUT 1710 reciting the unit length resistances of other wire materials and the corresponding reference cord diameter can also be applied in other embodiments of the invention. The reference cord diameter can be replaced by a normal diameter with unit of inches or millimeters. Alternatively, the reference cord diameter can be replaced by the cross-sectional area. Other conductive wire materials may include but may not be limited to iron, aluminum, silver, and so forth, which can be determined according to actual design or application requirements.

TABLE 1

| Unit length resistances Rᵤ of the copper wire | Reference cord diameter Aᵣ |
|---|---|
| (ohm/m) | (AWG) |
| 0.02095 | 18 |
| 0.02642 | 19 |
| 0.03331 | 20 |
| 0.04200 | 21 |
| 0.05296 | 22 |
| 0.06679 | 23 |
| 0.08422 | 24 |
| 0.10620 | 25 |

As a whole, if the external mobile apparatus 4000 is coupled to the I/O port 1601, the user may execute the APP 4100 designated by the external mobile apparatus 4000, and the length information L of the charging line 3000 can be provided by the APP 4100 to the processing circuit 1700 of the power bank apparatus 1000. The processing circuit 1700 can then look up the corresponding diameter of the charging line 3000 from the LUT 1710 according to the resistance R and the length information L of the charging line 3000. After that, the processing circuit 1700 may output the diameter of the charging line 3000 to the external mobile apparatus 4000 through the I/O port 1601. The APP 4100 of the external mobile apparatus 4000 then displays the diameter of the charging line 3000 for the user's reference.

For instance, if the conductive wire material of the charging line 3000 is copper, and the length L of the charging line 3000 is 50 cm, the resistance R of the charging line 3000 detected by the processing circuit 1700 is 0.021 ohm. The processing circuit 1700 can obtain the unit length resistance R_{d} of the charging line 3000 as 0.042 ohm/m according to the resistance R (0.021 ohm) and the length L (50 cm) of the charging line 3000. The processing circuit 1700 can then look up the corresponding diameter of the charging line 3000 as AWG 21 from the LUT 1710 (Table 1) according to the unit length resistance R_{d} (0.042 ohm/m) of the charging line 3000. After that, the processing circuit 1700 may output the diameter (AWG 21) of the charging line 3000 to the external mobile apparatus 4000 through the I/O port 1601. The APP 4100 of the external mobile apparatus 4000 then displays on a user interface the information of the charging line 3000, i.e., the diameter (AWG 21) of the copper wire.

In the previous embodiment, note that the charging line 3000 may not be the copper wire, and the user may not be aware of the conductive wire material of the charging line 3000; however, the power bank apparatus 1000 can still look up the corresponding diameter of the charging line from the LUT 1710 for the user's reference according to the resistance R and the length information L of the charging line 3000. For instance, in the previous embodiment, even if the conductive wire material of the charging line 3000 is not copper, the charging line 3000 may be deemed equivalent to the copper wire with the AWG 21 diameter. This is because the resistance R of the charging line 3000 and the resistance of the copper wire with the AWG 21 diameter are substantially the same, given the same length information L. Hence, the power consumption of the two stays substantially unchanged.

On the other hand, if the processing circuit 170 is unable to directly look up the corresponding diameter of the charging line 3000 from the LUT 1710 (Table 1) according to the unit length resistance R_{d} of the charging line 3000, the processing circuit 170 can look up the unit length resistances Rᵤ of two copper wires adjacent to the unit length resistance R_{d} of the charging line 3000 and obtain the diameter of the charging line 3000 through interpolation.

For instance, given that the processing circuit 1700 calculates the unit length resistance R_{d} of the charging line 3000 as 0.032 ohm/m, and that the processing circuit 170 is unable to directly look up the corresponding diameter of the charging line 3000 from the LUT 1710 (Table 1), the processing circuit 170 can look up the unit length resistances Rᵤ (0.02642 ohm/m and 0.03331 ohm/m) of two copper wires adjacent to the unit length resistance R_{d} (0.032 ohm/m) of the charging line 3000. The processing circuit 1700 can then obtain the diameter of the charging line 3000 as AWG 19.81 through interpolation.

The user interface where the length information L of the charging line 3000 is input and where the APP 4100 displays the diameter of the charging line 3000 can be deter mined according to the actual design or application requirements. The APP 4100 not only can input the length information L of the charging line 3000 but also can input the conductive wire material of the charging line 3000. The length information L of the charging line 3000 and the conductive wire material of the charging line 3000 can be directly input by the user through the user interface of the APP 4100, or the APP 4100 displays plural length information L or conductive wire materials of the charging line 3000 on the user interface for the user to select. Besides, in addition to displaying the diameter of the charging line 3000, the APP 4100 can individually display other parameters of the charging line 3000, e.g., the resistance R, the length information L, and the cross-sectional area of the charging line 3000; note that the invention should not be construed as limited to the embodiments set forth herein.

In the previous embodiments, an overly large resistance R of the charging line 3000 obtained by measurement often indicates the overly small diameter of the charging line 3000, the unfavorable conductivity of the conductive wire material of the charging line 3000, or an impairment of the charging line 3000. Hence, the user can determine whether the charging line is malfunctioned according to the resistance R or the diameter of the charging line 3000, whereby the user can then determine whether to replace the charging line 3000 or not. The user may also be capable of comparing the resistances R or the diameters of plural charging lines 3000 and selecting one of the charging lines 3000 according to actual design or application requirements.

The LUT 1710 reciting the unit length resistances of other wire materials and the corresponding reference cord diameter can also be built in the processing circuit 1700 according to an embodiment of the invention. Namely, each LUT 1710 corresponds to one conductive wire material, e.g., copper, iron, aluminum, silver, and so forth. Thereby, the user may input the conductive wire material and the length information L of the charging line 3000 through the APP 4100, and the processing circuit 1700 may look up the diameter of the charging line 3000 from the LUT 1710 (reciting the unit length resistances of the corresponding conductive wire material) according to the conductive wire material, the length information L, and the detected resistance R of the charging line 3000.

According to an embodiment of the invention, the APP 4100 of the external mobile apparatus 4000 may also include an LUT 4110 which is the same as the LUT 1710 of the processing circuit 1710 (e.g., including but not limited to Table 1). Thereby, the user may update the data in the LUT 4110 through downloading the latest APP 4100 of the external mobile apparatus 4000. Alternatively, the user may revise the data in the LUT 4110 based on actual design or application requirements. Please refer to FIG. 1 and FIG. 3 together. The processing circuit 1700 may output the resistance R of the charging line 3000 to the external mobile apparatus 4000 through the I/O port 1601. The APP 4100 of the external mobile apparatus 4000 may then look up the diameter of the charging line 3000 from the LUT 4110 of the APP 4100 according to the resistance R and the length information L of the charging line 3000. After that, the APP 4100 may display the diameter of the charging line 3000. The method of looking up the diameter of the charging line 3000 from the LUT 4110 by the APP 4100 is similar to and can be deduced from the aforesaid method of looking up the diameter of the charging line 3000 by the processing circuit 1700; therefore, no further explanation is provided hereinafter.

To sum up, the power bank apparatus described herein is configured to measure the resistance of the charging line. The length information or the conductive wire material of the charging line may then be input by the APP of the external mobile apparatus coupled to the power bank apparatus. The processing circuit of the power bank apparatus can look up the diameter of the charging line from the LUT of the processing circuit according to the resistance, the length information, or the conductive wire material of the charging line and output the diameter of the charging line to the external mobile apparatus. Alternatively, the processing circuit of the power bank apparatus can output the resistance of the charging line to the external mobile apparatus, and the APP of the external mobile apparatus can look up the diameter of the charging line from the LUT of the APP according to the resistance, the length information, or the conductive wire material of the charging line. The APP of the external mobile apparatus then displays the diameter or the resistance of the charging line. Thereby, the user is able to learn the impact of the charging line on the charging efficiency of the apparatus according to the resistance or the diameter of the charging line. The user can also determine whether the charging line is malfunctioned according to the resistance or the diameter of the charging line, whereby the user can then determine whether to replace the charging line or not.

Although the invention has been described with reference to the embodiments thereof, it will be apparent to one of the ordinary skills in the art that modifications to the described embodiments may be made without departing from the spirit of the invention. Accordingly, the scope of the invention will be defined by the attached claims not by the above detailed description.

What is claimed is:

1. A power bank apparatus configured to measure resistance of a charging line, the power bank apparatus comprising:
at least one input port configured to receive from at least one external power supply at least one input power signal as at least one test signal through at least one charging line;
at least one first detection circuit coupled to the at least one input port to receive the at least one test signal, wherein the at least one first detection circuit is configured to detect a voltage of the at least one test signal as at least one no-load voltage if the at least one external power supply is in a no-load state, and the at least one first detection circuit is configured to detect the voltage and a current of the at least one test signal as at least one load voltage and at least one load current if the at least one external power supply is in a load state; and
a processing circuit coupled to the at least one first detection circuit, the processing circuit receiving the at least one no-load voltage, the at least one load voltage, and the at least one load current to calculate the resistance of the at least one charging line.

2. The power bank apparatus according to claim 1, further comprising:
a charge control unit coupled to the at least one input port to receive the at least one test signal, the charge control unit being controlled by the processing circuit, so as to convert the at least one test signal and thereby generate a charge signal; and
a battery coupled to the charge control unit, the battery receiving the charge signal, so as to be charged.

3. The power bank apparatus according to claim 2, wherein the battery acts as a load of the at least one external power supply,
the processing circuit disables the charge control unit to stop converting the at least one test signal, such that the at least one external power supply is in the no-load state, and
the processing circuit enables the charge control unit to start converting the at least one test signal, such that the at least one external power supply is in the load state.

4. The power bank apparatus according to claim 2, further comprising:
at least one input/output port coupled to the processing circuit, the processing circuit communicating with at least one external mobile apparatus through the at least one input/output port.

5. The power bank apparatus according to claim 4, wherein the processing circuit comprises at least one look-up table, the processing circuit receives length information of the at least one charging line from the at least one external mobile apparatus through the at least one input/output port, the processing circuit looks up a diameter of the at least one charging line from the at least one look-up table according to the resistance and the length information of the at least one charging line, and the processing circuit outputs the diameter of the at least one charging line to the at least one external mobile apparatus through the at least one input/output port.

6. The power bank apparatus according to claim 5, wherein the at least one external mobile apparatus comprises an APP, the length information of the at least one charging line is provided to the processing circuit of the power bank apparatus through the APP, and the APP is configured to display the diameter of the at least one charging line.

7. The power bank apparatus according to claim 5, the at least one look-up table comprising:
a plurality of unit length resistances; and
a plurality of reference cord diameters,
wherein each of the unit length resistances corresponds to one of the reference cord diameters.

8. The power bank apparatus according to claim 7, wherein the at least one look-up table corresponds to at least one conductive wire material.

9. The power bank apparatus according to claim 4, wherein
the processing circuit outputs the resistance of the at least one charging line to the at least one external mobile apparatus through the at least one input/output port,
an APP of the at least one external mobile apparatus looks up a diameter of the at least one charging line from the at least one look-up table of the APP according to the resistance of the at least one charging line and length information of the at least one charging line, and the APP is configured to display the diameter of the at least one charging line.

10. The power bank apparatus according to claim 4, further comprising:
a discharge control unit coupled between the battery and the at least one input/output port, the discharge control unit being controlled by the processing circuit, so as to convert a voltage of the battery and thereby generate at least one discharge signal,
wherein the at least one input/output port receives the at least one discharge signal as at least one output power signal and provides the at least one output power signal to the at least one external mobile apparatus.
